(19) United States
(12) Patent Application Publication
(10) Pub. No.: US 2020/0386787 A1
(43) Pub. Date: Dec. 10, 2020

(54) REUSABLE PROBE CARD WITH REMOVABLE PROBE INSERT

(71) Applicant: Texas Instruments Incorporated, Dallas, TX (US)

(72) Inventors: Yazdi Dinshaw Contractor, Tucson, AZ (US); Gerard Riddick, Tucson, AZ (US); Ray Joseph Ochotorena, Jr., Corona de Tucson, AZ (US); John Allen Hite, Forney, TX (US); William Edward Brumley, Tucson, AZ (US); Enrique Teran, Tucson, AZ (US)

(21) Appl. No.: 16/432,704

(22) Filed: Jun. 5, 2019

(51) Int. Cl. G01R 1/073; G01R 31/26; G01R 31/01; G01R 1/067; H01L 21/66; H01L 21/56; H01L 23/00

(52) U.S. Cl. CPC G01R 1/07378; G01R 1/07342; G01R 1/07371; G01R 31/2601; H01L 2224/92247; G01R 1/06727; H01L 22/20; H01L 21/561; H01L 24/92; G01R 31/01

(57) ABSTRACT

In a described example, a device includes: a probe card with a tester side surface and a device side surface opposite the tester side surface; a probe insert having a first surface that is removably affixed to the device side surface of the probe card; and at least one or more probes extending from a second surface of the probe insert that is opposite the first surface of the probe insert.

### TECHNICAL FIELD

This disclosure relates generally to semiconductor devices, and more particularly to probe cards for testing semiconductor devices at the wafer level and for other test applications, such as at final test for packaged semiconductor devices.

### BACKGROUND

In manufacturing semiconductor devices, testing is used to verify proper functionality of the devices. The tests identify good and failing devices to ensure only good devices are completed and sold. A wafer prober is often used. A tester is connected to a wafer prober station, alternatively the wafer prober and tester are combined in a single tool. A probe card is positioned in the wafer prober with probes that can be placed in contact with a device under test (“DUT”) on a wafer. For example, a semiconductor device can be manufactured on a semiconductor wafer. The wafer prober is electrically coupled to the tester and test programs are executed that exercise the device under test (“DUT.”) Data is collected from the DUT. The data can be used to determine whether the DUT is functional, and information about device speed and other parametric information can be collected about the performance of the DUT. Failing devices can be identified, alternatively, passing devices can be identified. In some probe stations, temperature testing, and burn-in or cycle testing can be performed at the wafer level to verify which devices meet performance requirements.

Wafer probers are used to test semiconductor die when the manufacturing of the semiconductor die are almost complete, but while the die are still part of a semiconductor wafer. Because manufacturing a packaged semiconductor device includes several expensive and time consuming steps that are performed after the devices are complete at the wafer stage (sometimes referred to as “back end” processes), it is important to identify good semiconductor device die and to identify failing die on the semiconductor wafer before the packaging steps are performed. By eliminating failing die from the expensive packaging steps, substantial costs can be saved, because these steps are not performed on failing die. In this manner, scrap can be avoided and manufacturing costs are reduced.

Device testing is also performed using wafer probers on packaged semiconductor devices. The tests are performed by placing the probes in contact with terminals on the packaged semiconductor devices and applying signals to the terminals. Data can be collected from the packaged DUTs in response to the signals. This is sometimes referred to as “final testing” or “FT.” In some arrangements, the FT testing is performed when the packaged devices are still connected together in a strip or array of packaged devices, and this test is sometimes referred to as “FT/strip test.” Passing devices can then separated from and picked from the array of devices and shipped.

Probe cards are used to interface between the test equipment and DUTs in the wafer prober. A probe card is a complex customized circuit board with a plurality of signal traces formed between terminals for coupling the probe card to the test equipment and to the probes. Because the DUTs are semiconductor die with very small bond pad terminals, the probes are often fine conductive elements that extend from the probe card. The probes can be needles and are sometimes referred to as “probe needles.” The probe card has probe needles extending from the probe card with probe tips arranged in a pattern that matches the pattern of the bond pads or terminals the probes are to contact during testing.

Probe cards are customized, expensive, and critically engineered circuit boards. Several probe cards are needed for each newly produced semiconductor device and/or each new packaged semiconductor device. The probe cards take substantial time to design, manufacture and test prior to use. The need for a new probe card to test a newly introduced device can delay the time to market for a new semiconductor device. Probe cards are large and require substantial storage space and maintenance. For example, probe cards can be 10-14 inches in diameter or larger.

### SUMMARY

In a described example, a device includes: a probe card with a tester side surface and a device side surface opposite the tester side surface; a probe insert having a first surface that is removably affixed to the device side surface of the probe card; and at least one or more probes extending from a second surface of the probe insert that is opposite the first surface of the probe insert.

In the arrangements, the probe card is reusable with a variety of the removable probe inserts. In a testing method, the probe card and the probe insert are used to test DUTs on a semiconductor wafer. In another testing method, the probe card and the probe insert are used to test DUTs on a strip of packaged semiconductor devices, or to test individual packaged semiconductor devices.

### BRIEF DESCRIPTION OF THE DRAWINGS

FIG. 1 illustrates in a block diagram a test system with a wafer prober using a probe card.

FIG. 2 illustrates in a bottom up view a probe card.

FIG. 3 illustrates in a cross sectional view a probe card and probes.

FIG. 4 illustrates in a partially exploded projection view of an example arrangement for a probe insert and probe card.

FIG. 5 illustrates in a projection view the test side surface of a probe card with an aperture according to an embodiment.

FIG. 6 illustrates in a projection view an alignment plate for use with the arrangements according to an embodiment.

FIG. 7A illustrates in a projection view a testers side of a probe card with the alignment plate placed on the tester side surface, while FIG. 7B illustrates in a projection view the device side of the probe card with pins from the alignment plate in FIG. 7A extending through apertures in the probe card and away from the device side surface of the probe card according to an embodiment.

FIG. 8 depicts a projection view of the tester side of a probe card arrangement with a top plate affixed to a tester side surface of the probe card according to an embodiment.

FIGS. 9A and 9B depict a projection view and a cross sectional view of an interposer and terminals for use with the arrangements, FIG. 9C depicts a projection view of a device side of a probe card with interposers attached to the probe card according to an embodiment.

FIG. 10A illustrates a tester side surface of a probe insert of the arrangements including a top block, FIG. 10B illustrates a device side surface of the probe insert of FIG. 10A according to an embodiment.

FIG. 11A illustrates in a projection view a tester side of a probe card of the arrangements with a probe insert attached to a top plate; FIG. 11B illustrates a device side plan view of the probe card of FIG. 11A with a probe insert mounted to the probe card′ FIG. 11C is a across sectional view of the probe card of the arrangements and a probe insert attached to the probe card; FIG. 11D is a cross sectional view of a wafer prober with the probe card of the arrangements shown with a device under test in the wafer prober according to an embodiment.

FIG. 12 illustrates in a flow chart a method arrangement according to an embodiment.

FIGS. 13A-13B illustrate a semiconductor wafer with passing and failing semiconductor devices marked, and a single semiconductor device, respectively according to an embodiment.

FIGS. 13C-13G depict in a series of cross sections major steps in packaging semiconductor devices after being tested using the arrangements according to an embodiment.

FIG. 13H illustrates in a projection view a packaged semiconductor device according to an embodiment.

FIG. 14 illustrates in a flow diagram a method arrangement for packaging semiconductor devices using the arrangements according to an embodiment.

### DETAILED DESCRIPTION

Corresponding numerals and symbols in the different figures generally refer to corresponding parts, unless otherwise indicated. The figures are not necessarily drawn to scale.

As is further described hereinbelow, certain structures and surfaces are described as “perpendicular” to one another. For purposes of this disclosure, two elements are “perpendicular” when the elements are intended to form a 90-degree angle at their intersection. However, the term “perpendicular” as used herein also includes surfaces that may slightly deviate from an angle 90 degrees at the intersection due to manufacturing tolerances. The term “vertical” indicates a direction generally perpendicular to a horizontal surface, such as the surface of a semiconductor wafer or a printed circuit board lying on a table.

The term “coupled” is used herein. As used herein, two elements are coupled when the elements are electrically connected. An element is coupled to another element even when there are intervening elements.

The terms “planar” and “co-planar” are used herein. A surface of an element is planar when it lies in a single plane. However, in manufacturing, variations occur. As used herein, a surface is “planar” if it is intended to lie in a single plane even if some portions of the surface outside the single plane due to tolerances or variations that occur in manufacture of the surface. Two surfaces are “co-planar” when the two surfaces are intended to lie in a single plane, even if when manufactured one or both surfaces vary from the single plane.

The term “scribe lane” is used herein. A scribe lane is a portion of semiconductor wafer between semiconductor devices. Sometimes in related literature the term “scribe street” is used. Once semiconductor wafer processing is finished and the semiconductor devices are complete, the semiconductor devices are separated into individual semiconductor die by severing the semiconductor wafer along the scribe lanes. This process is often referred to as “singulation.” Scribe lanes will be arranged on four sides of a semiconductor device and when singulated from one another, rectangular semiconductor die are formed. The term “saw streets” is used herein. As used herein, a saw street is a portion of a lead frame strip between lead frames that have semiconductor devices mounted to them. After packaging with mold compound is completed, the packaged semiconductor die are singulated one from another by cutting through the lead frame strip and the mold compound in the saw streets to form individual semiconductor packages.

In the arrangements, the problem of providing a probe card for testing a device is solved by providing a reusable probe card with a removable probe insert. The removable probe insert includes probes with tips extending from the probe insert, the probe tips arranged in a pattern corresponding to electrical terminals of a DUT. The probe card includes features to insure the correct alignment of the probes when the probe insert is removably attached to the probe card, including alignment features for ensuring alignment of the probe insert to the probe card. By use of the arrangements, the probe insert can be replaced with a different probe insert for testing different DUTs, without the need to replace the probe card. Use of the arrangements provides a reusable probe card for many different products to be tested. The probe inserts are smaller and cheaper to manufacture than a probe card, and storage for the probe inserts requires less space than storing probe cards. In an example, the probe insert is rectangular or square and can be, for example, about 3-4 inches across. Other sizes can be used for the probe insert. Probe cards can be circular and can be 10 or more inches in diameter. Replaceable probe inserts of the arrangements are cheaper, faster to design and produce and smaller than probe cards, and therefore use of the arrangements lowers costs and reduces time to market when compared to manufacturing new probe cards. The use of the replaceable probe inserts of the arrangements also results in reusable probe cards, reducing the number of probe cards needed.

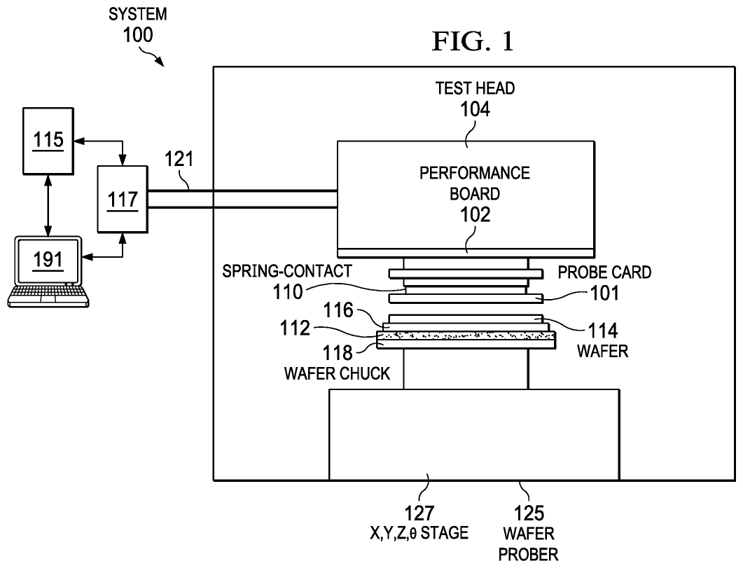

FIG. 1 depicts a test system 100 that uses a probe card 101. System 100 includes a test computer 191 which can be a workstation, computer, laptop, desktop or other computer capable of executing software programs, and capable of receiving user inputs, a tester 115 which has stored test patterns, stored test programs and which can store test results, and an interface unit 117 for providing input and output signals on leads 121. For “at speed” testing leads 121 can be shielded, high frequency, or for testing power devices, can be high power conductors. A wafer prober 125 includes a test head 104 that can include a performance board 102 for transmitting to and receiving signals from a device under test, and a spring contact arrangement 110 for making electrical contact between the performance board and the probe card 101. The probe card 101 carries the probes that will contact the DUT (not visible in this view).

Wafer prober 125 includes a wafer stage 127 that transports the wafer, package strip, or integrated circuit, including the devices under test, in x, y and z directions, and which can tilt at an angle “theta” to align the terminal of the device under test to the probe card and to the probes. The wafer 114 (or other device under test) rests on a vacuum chuck 118. A heater/chiller 112 can be included for thermal testing. The wafer 114 is quite thin and may be supported by a backgrinding tape or other tape 116 to prevent flexing of the wafer. The wafer prober also includes a loading and unloading mechanism, for example a robot may select a wafer from a wafer cassette, load it onto the vacuum chuck, and after testing is complete, unload it from the vacuum chuck and place it back in a wafer cassette for transport. (For simplicity of illustration, the wafer loading and transport portions are omitted.)

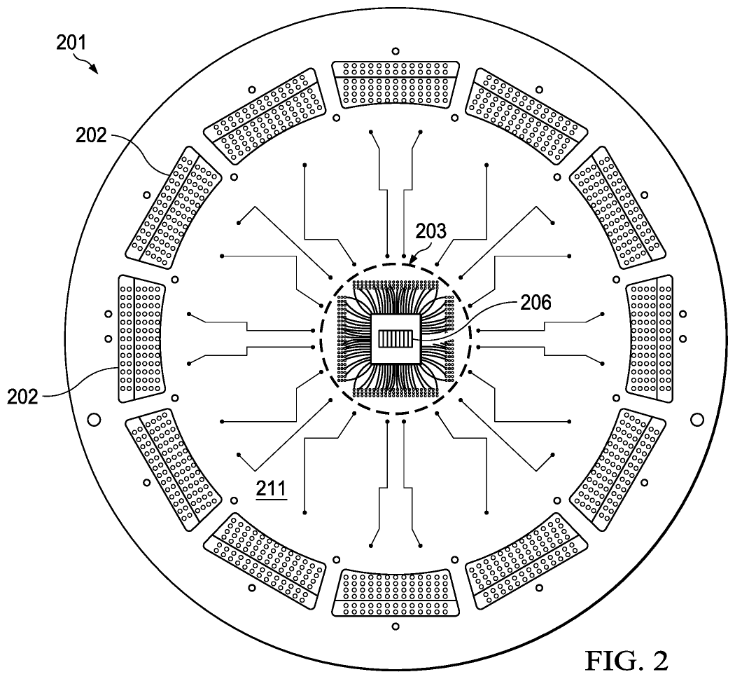

FIG. 2 is a bottom view of a probe card 201 which corresponds to probe card 101 in FIG. 1. For ease of understanding, similar reference labels are used for similar elements between the figures, for example, probe card 201 corresponds to probe card 101. The probe card 201 includes a printed circuit board 211. The printed circuit board can be a dielectric material used for circuit boards such as fiber reinforced glass (FR4), bismaleimide-triazine (BT) resin, or other dielectric material used for circuit boards. Traces on the circuit board 211 are conductive and couple test connectors 202, which provide electrical connection to the tester, to the probes 206. Probes 206 can be cantilever needle probes as shown in this example, and in addition the probes can be vertical probes, or can be blade probes. The probes in this example are needle probes mounted on an epoxy ring 203 for support, the ring is mounted to the printed circuit board 211 and one end of the needles are electrically connected to traces on the circuit board 211 of probe card 201. When the probe card 201 is mounted in a wafer prober, the probe needles 206 are electrically coupled through the redistribution layers on the circuit board 211 to test connectors 202, which can be conductive pads that coupled to the tester or performance board. Cables or board to board interconnects can be used to couple to test connectors 202.

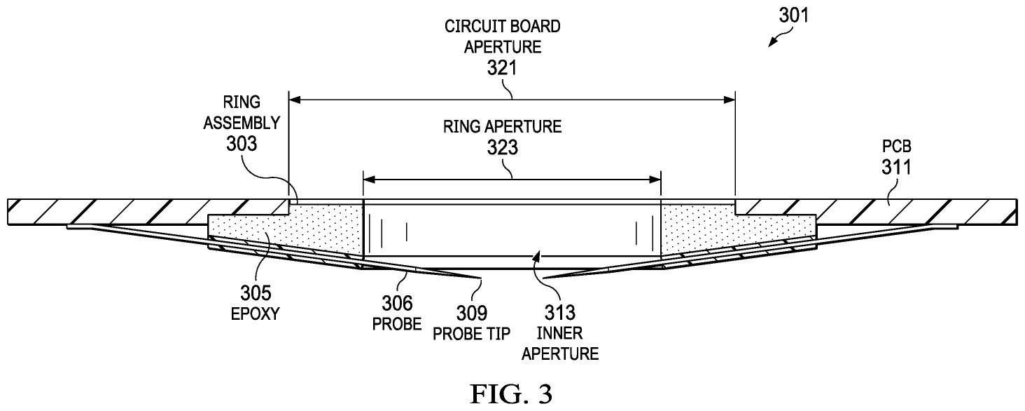

FIG. 3 is a cross section of an example cantilever probe card 301. In FIG. 3, similar reference numerals are used to reference numerals in FIG. 2 for similar elements, for clarity. For example, probe card 301 in FIG. 3 corresponds to probe card 201 in FIG. 2.

In FIG. 3 the probe card 301 includes a printed circuit board (PCB) 311. An aperture 321 is in the central portion of the PCB 311. Ring assembly 303, which can be formed of an insulating material such as an epoxy or resin 305, is shown installed in the aperture 321 and affixed to the circuit board 311. Ring assembly 303 also has a central ring aperture 323. The needles are affixed to the ring assembly 303 by an epoxy 305, the ring assembly 303 is also sloped to direct the needles away from the probe card 301 and form the cantilever arrangement for the probes 306. The probes 306 end in probe tips 309 that are arranged in a pattern to correspond to bond pads, terminals, or test structures on the DUT that the probes are to make electrical contact to. During a test, probes 306 will provide power, ground and signals to the DUT so as to enable the DUT to operate during the test. The probes 306 are electrically coupled at an end away from the probe tips 309 to conductive traces on the circuit board 311, for example by soldering. The probes 306 are therefore electrically coupled to traces on the probe card printed circuit board 311 that carry power, ground or other signals to and from the probes and to and from the tester.

Probe cards can be of different types. Cantilever probe cards such as shown in FIG. 3 are used in some applications. Cantilever probe needles are mounted to angled supports on the probe card, and the probe needles extend from the probe card at an angle to a horizontal surface of the probe card, and are shaped to form a coplanar array of probe tips that correspond to a pattern of electrical terminals on the DUT. Blade probe cards are used. A blade shaped holder affixed to the probe card supports each probe, the blades are mounted to the probe card around a central aperture and extend through the central aperture, and the probes extend away from the probe card perpendicular to a surface of the probe card, so that the probe tips again form a coplanar array in a pattern corresponding to the electrical terminals of a DUT. Vertical probes can be used with a probe card where the probes are pins or needles that are placed perpendicular to a horizontal surface of the probe card, and extend from the probe card and form parallel probes with the tips of the probes forming a coplanar pattern corresponding to the electrical terminals of a DUT. The probe tips should be coplanar or nearly so with respect to one another. Keeping the probe tips coplanar over thousands of landings on DUTs is one critical aspect of probe testing with probe cards. The probe tips are small and fragile and have to be carefully handled and maintained to ensure planarity so that all of the tips are in good physical contact with the pads or terminals of the DUT at the same time. The probe card and the DUT have to be kept in proper alignment so that when the DUT and the probe tips are placed in contact for testing, all of the probe tips make contact for good electrical coupling. All of these types of probes are useful in the arrangements as described hereinbelow.

A DUT can have a few, several, tens, hundreds or thousands of terminals, depending on the type of device being tested. When DUTs have few terminals, the probes can be arranged to test several devices simultaneously, for example when three terminal transistor devices are formed on a semiconductor wafer, many of these devices can be contacted by the probes and tested in parallel. In contrast, complex semiconductor die such as, for example, a semiconductor device that forms a system on a chip for a cellular phone, may be tested one device at a time, because of the much greater number of terminals for the semiconductor device. Traces on the probe card can be routed and arranged to avoid crosstalk or noise between these traces used with high frequency devices during testing.

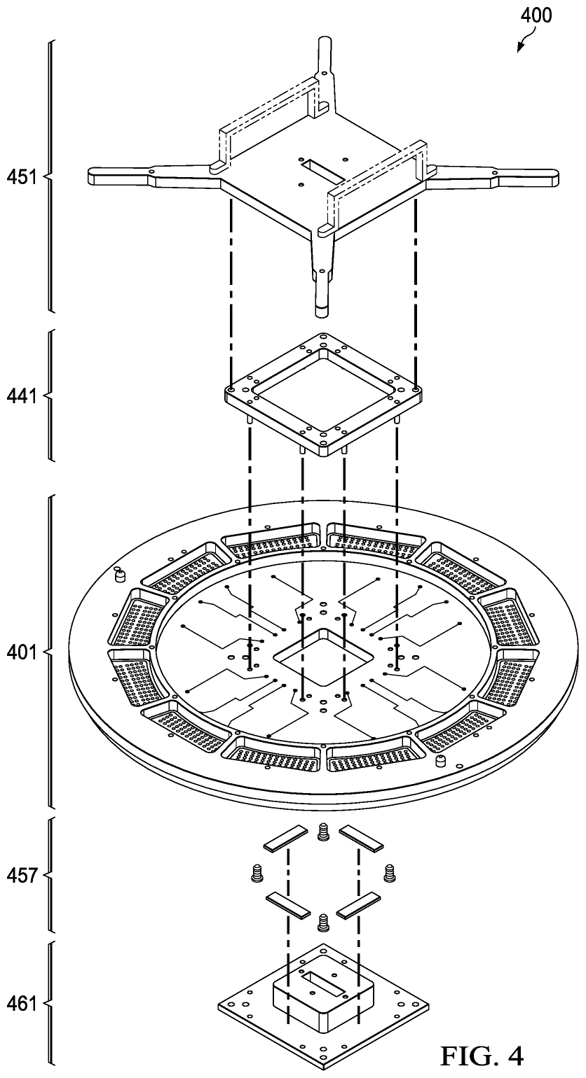

FIG. 4 is an exploded view of an example arrangement 400. In FIG. 4, a probe card 401 is shown. In an example the probe card is about 10-11 inches in diameter, although larger or smaller probe cards can be used. A removable probe insert 461 is arranged to be removably attached to a device side of the probe card 401. Interposers 457 are placed between the probe insert 461 and the probe card 401 and provide electrical coupling between pads on the probe insert 461 and corresponding pads on the wafer side of probe card 401. In an example the probe insert is about 3 inches across and is square with evenly long sides. Other examples could include probe inserts that are 4 inches square. Other shapes and sizes can also be used, for example, the probe insert could be rectangular, octagonal, triangular, oval or circular.

A top plate 451 is shown on the tester side of the probe card 401 and will attach to the probe card 401. An alignment plate 441 attaches to the tester side of probe card 401 between the probe card 401 and the top plate 451. Top plate 451 has optional handles to make handling the assembly 400 easier. Alignment plate 441 provides mechanical alignment for the interposers as is further described hereinbelow.

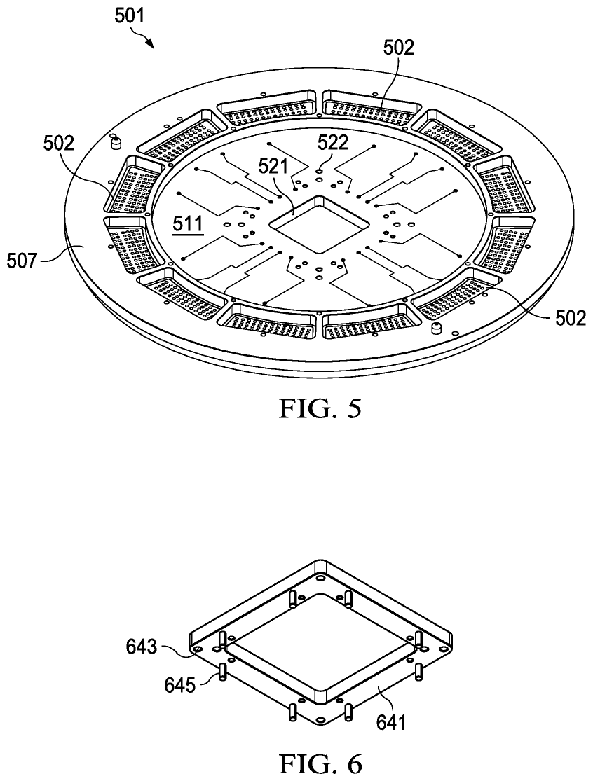

In the figures that follow, each of the elements of the arrangement in FIG. 4 is further detailed. FIG. 5 is a projection view of a probe card 501 viewed from a tester side of the probe card, the side that is going to be electrically coupled to the tester. For ease of understanding, the reference numerals in FIG. 5 are similar to those in FIG. 4, for example, probe card 501 corresponds to probe card 401 in FIG. 4. The probe card 501 has tester contact ports 502 that provide an array of contact pads for use in coupling the traces and circuitry on probe card 501 to signals from the tester. Contact interposers (not shown for clarity) can be used to contact a performance board (not shown) in a tester to the probe card tester contact ports 502. In an alternative, cables or connectors that connect to the array of pads in each port 502 can be used to electrically couple the probe card 501 to a tester.

Probe card 501 includes a circuit board 511 and a stiffener 507 overlying and attached to the circuit board 511. The circuit board 511 can be any substrate used for circuit boards, examples include fiber reinforced glass substrates such as FR4, BT resin, and other dielectric materials such as insulating films. The circuit board 511 can have multiple layers of insulators and conductors to provide conductive paths between the tester contact ports 502 and probe contact ports (not shown) on the device side of the probe card 511 (not visible in this view). A central aperture 521 is provided in the center of the probe card 501. Holes 522 in the circuit board 511 can provide mounting holes for different parts of the arrangement, or can be alignment features, as is further described hereinbelow. Stiffener 507 can be stainless steel or another material that adds mechanical stiffness to circuit board 511. A stiffer probe card prevents problems with probe alignment that might occur without the stiffener 507, however, in alternative arrangements, the stiffener 507 can differ from the one shown in this example, or can be omitted. For example, if a stiffer circuit board material is used for circuit board 511, the stiffener 507 can be omitted. (In an arrangement where the stiffener is omitted, a top plate described later herein will then attach to the circuit board 511 instead of to the stiffener 507).

In contrast to the probe card of FIG. 3, in this example arrangement the probe card 501 does not include probes, instead the probe card 501 will receive a removable probe insert (described hereinbelow) that includes the probes, as is further described. Because the probe card 501 does not include the probes, the probe card 501 can be reusable for testing different devices, including semiconductor die and packaged semiconductor devices, and can remain installed in the wafer prober when different devices are tested. In contrast to the prior approaches, a custom probe card is not needed for each new product to be tested. Instead, a removable probe insert is used to configure the reusable probe card for different DUTs.

FIG. 6 is a projection view of the probe card side of an alignment plate 641. The alignment plate 641 corresponds to alignment plate 441 in FIG. 4. The alignment plate 641 has mounting holes 643 for attaching the alignment plate to the tester side of probe card (such as 501 in FIG. 5). The vertical pins 645 will extend through corresponding holes in the probe card and will provide alignment features for interposer connectors, as is described hereinbelow. The alignment plate 641 and alignment pins 645 ensure proper alignment of the probe insert and interposer connectors described hereinbelow when these elements are assembled together.

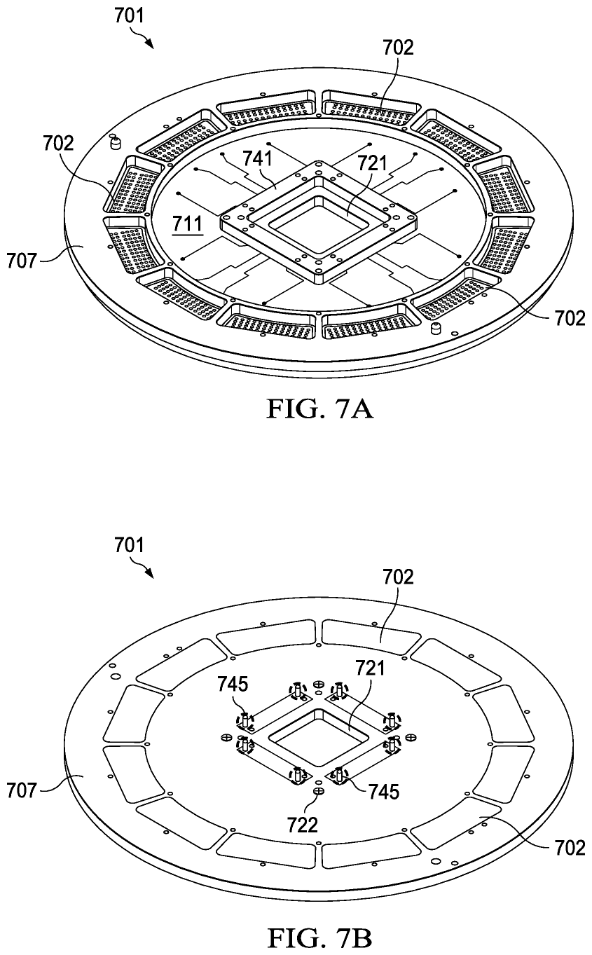

FIGS. 7A and 7B illustrate in projection views an alignment plate 741 corresponding to alignment plate 441 in FIG. 4 mounted to a probe card 701. In FIGS. 7A-7B, similar reference labels are used for similar elements in earlier figures, for clarity of understanding. For example, probe card 701 corresponds to probe card 401 in FIG. 4. In FIG. 7A, a view from the tester side of a probe card 701 includes a printed circuit board 711 with a stiffener 707, tester connection ports 702, a central aperture 721, and alignment plate 741 mounted to the circuit board 711 with the opening of the alignment plate in correspondence with the central aperture 721 in board 711.

FIG. 7B illustrates the probe card 701 viewed from the device side, opposite the tester side of the probe card 701 shown in FIG. 7A. Pins 745, which are provided by alignment plate 741 shown in FIG. 7A (see also pins 645 in FIG. 6), extend through corresponding through holes in probe card 701. Connectors 722, in this example screws, attach the alignment plate 741 to probe card 701. Pins, clips, clamps, rivets, bolts, tapes or other attachment types can be used to attach the alignment plate 741 to probe card 701. Further, in an alternative, the alignment pins 745 can be provided using multiple alignment plates, or by providing other attachment points, to form additional alternative arrangements.

FIG. 8 illustrates in a projection view a probe card 801 from the tester side. Probe card 801 corresponds to probe cards 701, 501, and 401. In FIG. 8, a circuit board 811 has a stiffener plate 807 attached to the tester side of the circuit board. Tester connector ports 802 provide arrays of electrical contacts to allow connection to signals from a tester. In FIG. 8, connectors 853 attach a top plate 851 to the stiffener 807. In this example the top plate 851 is stainless steel, although in alternative arrangements other materials can be used. The connectors 853 in this example are screws, however in additional alternatives other connectors such as pins, clamps, bolts, and rivets can be used. In this example arrangement, top plate 851 provides a mount for the probe insert (described below) and aids in aligning the probe insert to the probe card. As shown in FIG. 8, holes 855 in the top plate provide a probe insert mounting area. The holes in this example are offset from one another in position to “key” the mounting area, so that when a probe insert is removably attached to the top plate, as described further hereinbelow, the probe insert can only be attached when it is in a proper position, preventing placement errors. Optional handles 857 are attached to the top plate 851 to aid in mounting the probe card in a wafer prober. The top plate 851 attaches to the probe card using four simple removable connectors 853, here simple screws with Philips heads, to enable fast assembly manually using simple hand tools, handheld power tools, or by using simple automated tools in a few minutes.

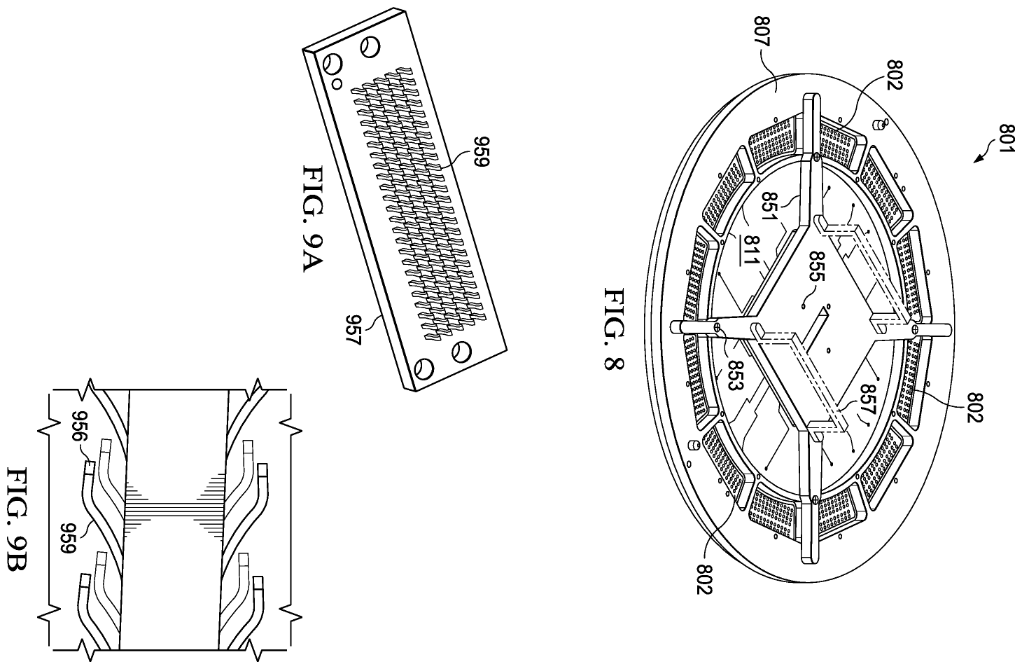

FIGS. 9A-9B illustrate in a projection view and a detailed view an example interposer connector useful with the arrangements. In FIG. 9A, an interposer connector 955 for connecting circuit boards electrically is shown. Interposer 957 corresponds to the interposers 457 in FIG. 4. Contacts 959 are shown arranged in rows and columns. The contacts 959 will match a pattern of electrical contact pads on the probe card and on the probe insert as described hereinbelow. In FIG. 9B, the detail of the interposer contacts can be seen with the contacts 959 having tips 956. The contacts of the interposer 957 are conductive mechanical springs with an end on each side of a dielectric substrate. When the interposer 957 is mechanically compressed between two circuit boards, the contacts 959 on the interposer provide an electrical connection between a probe card and a probe insert on either side of the interposer. These interposers provide multiple electrical connections between boards in a small footprint area without the need for solder or cables, and the arrangement can be assembled quickly by mounting the interposers to one board and aligning the second board, and then mechanically compressing the interposers such as 957 between corresponding contact pads on the two boards. In the arrangements, the interposer connectors are used to electrically connect the probe card to the probe insert. Board interposer connectors such as 957 are commercially available. One example arrangement uses an interposer available from NeoConix Incorporated, San Jose Calif., with part number SPH1-F120A. Interposer connectors with a variety of standard layouts are available and useful with the arrangements. The interposer connectors can be used to couple from board to board, as in the arrangements, or from a board to a flat cable. When the probe card contact patterns are determined, the standard interposer provides the required contact layout and positions, and similarly, when the probe insert contacts are determined, these are arranged in correspondence with the selected interposer and the probe card contacts.

FIG. 9C illustrates a view of a device side of a probe card 901 with interposer connectors 957 arranged on contacts surrounding the aperture 921. Alignment pins 945, which correspond to pins 745 in FIG. 7, are shown extending from the probe card 901 and the alignment pins provide alignment between the interposers 955 and the probe card 901. By placing the pins 945 through corresponding holes in the interposers 955, the interposers are aligned to the probe card. (The bottom surface of a top plate 951 is visible thought the aperture 921).

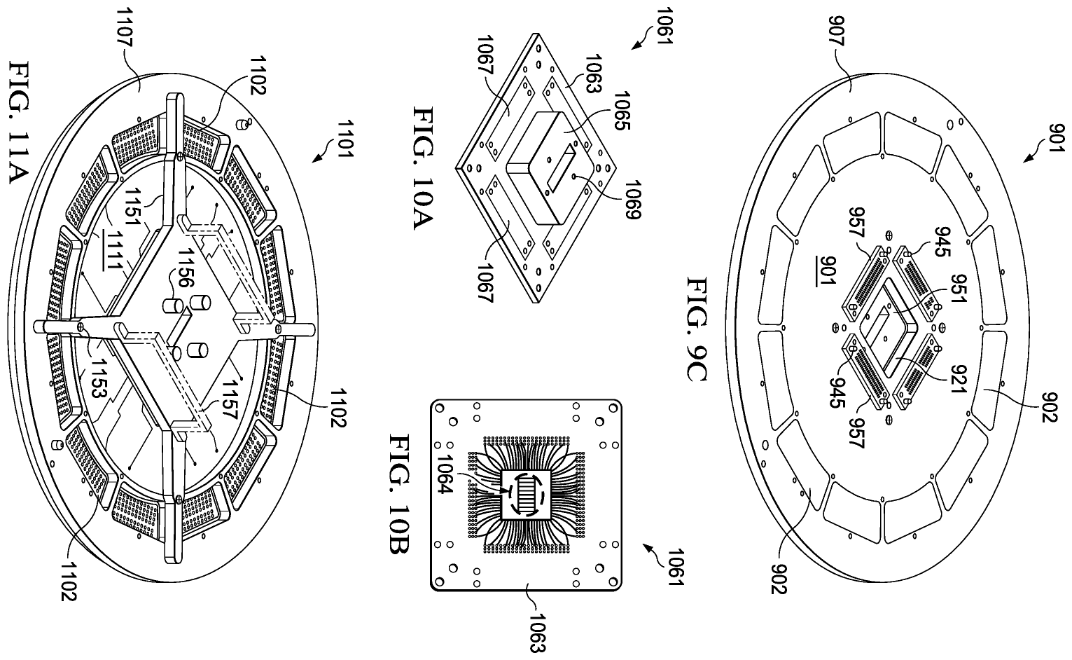

FIGS. 10A-10B are a probe card side view and a device side view, respectively, of a removable probe insert 1061 useful in the arrangements. Probe insert 1061 corresponds to probe insert 461 in FIG. 4. In FIG. 10A, a probe card side (top side as oriented in FIG. 4) of the probe insert 1061 is shown. A block 1065 is affixed to the probe card side of the probe insert. The probe insert 1061 includes a circuit board 1063 which can be a circuit board material such as a fiber reinforced glass (FR4), BT resin circuit board, or other dielectric material used for circuit boards. Threaded holes 1069 are formed into the block 1065 and the locations of the threaded holes 1069 correspond to the through holes in the top plate (not shown, but see top plate 851 and holes 853 in FIG. 8). Holes 1069 can be offset from one another to provide a “keyed” mounting position so that when the probe insert 1061 is mounted to the top plate of a probe card, correct positioning is assured. Contact areas on probe insert 1061 are formed into four contact areas 1067 arranged around the block 1065. The contacts provide electrical connections to the probe insert 1061. The contacts are arranged in a pattern of rows and columns to correspond to the pattern of an interposer connector to be used with the probe insert, such as 957 in FIG. 9.

FIG. 10B illustrates the device side surface of probe insert 1061. The circuit board 1063 has contacts and traces that electrically couple the probe needles (seen in the probe region 1064) to the contacts 1067 seen on the opposing side of the probe insert in FIG. 10A. Although in this example probe insert, cantilever probe needles are shown, in alternative arrangements, the probe needles in region 1064 can be vertical probes with vertical needles to form additional arrangements. Also, in this example the probe needles seen in region 1064 are arranged to contact a DUT in the form of an individual semiconductor die on a wafer, while in alternative arrangements the probe insert can carry probes such as probe needles arranged to contact a packaged semiconductor device (or a strip of packaged semiconductor devices) to perform final testing of a complete packaged device.

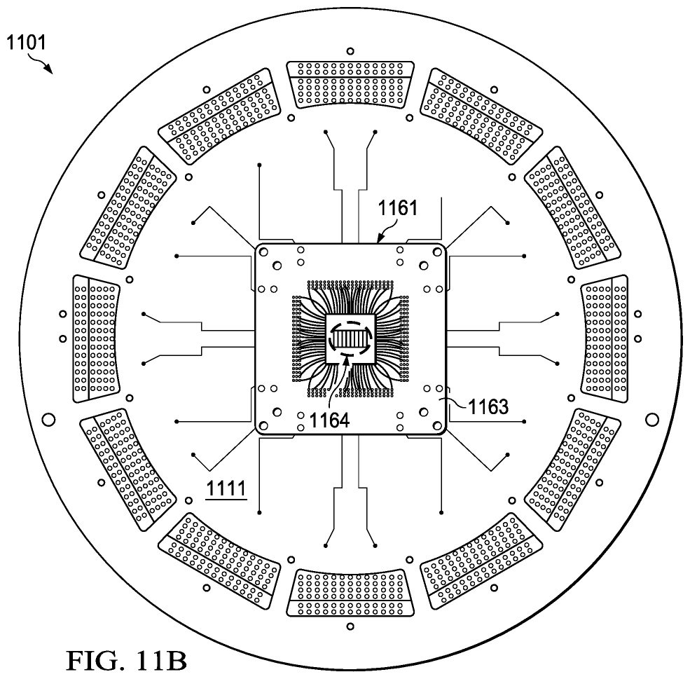

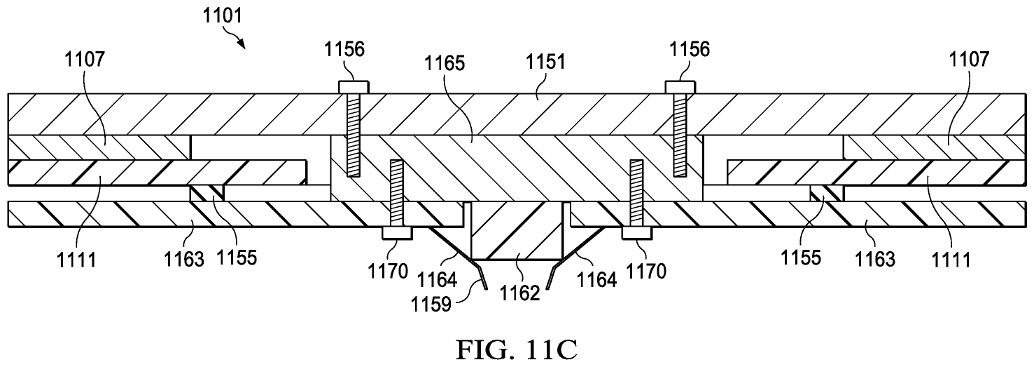

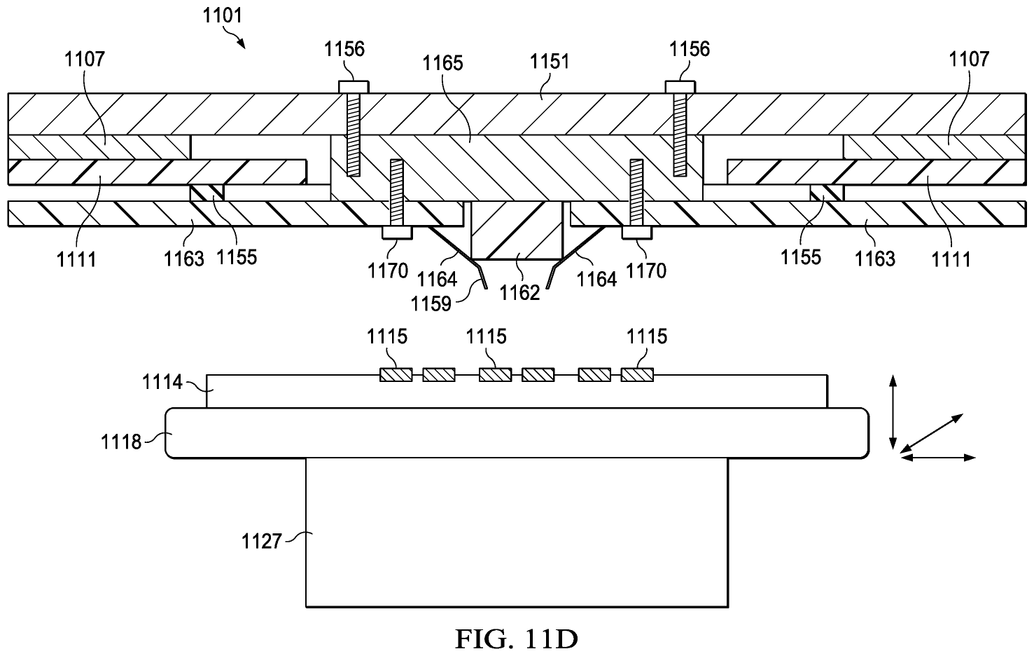

FIGS. 11A and 11B are projection views of an arrangement. In FIG. 11A, a probe card 1101 is shown in a tester side view which corresponds to probe card 801 in FIG. 8, now with a removable probe insert installed. In FIG. 11A, printed circuit board 1111 is shown with a stiffener 1107. Top plate 1151 is attached to the stiffener 1107 and connectors 1156 are used to attach a probe insert (see FIG. 11B, probe insert 1161) to the top plate. Handles 1157 are optional and used to allow for ease of handling of the probe card 1101. Connectors 1153, in this example simple Philips head screws, attach the top plate 1151 to the stiffener 1107. The connectors 1156 in this example are thumb screws to enable rapid and easy manual attachment and detachment of the removable probe insert. Screws, clamps, bolts, nuts and other removable connectors can be used as alternative to the thumb screws 1156. The thumbscrews 1156 extend through corresponding holes in the top plate 1151 and extend into threaded holes in the probe insert (not visible, but see probe insert 1061 with holes 1069 shown in FIG. 10A.)

FIG. 11B is a plan view of the device side of probe card 1101 with the probe insert 1161 mounted to the probe card 1101. In FIG. 11B, probe insert 1161 includes a circuit board 1163 and probes 1164. In this example, probes 1164 are cantilever probe needles. The cantilever probes are supported in a middle portion of the probes by an epoxy ring, and have one end that is electrically coupled to wires and traces on the circuit board 1163, the other end forms the probe tips (see, 1159 in FIG. 11C).

FIG. 11C is an example cross sectional view of an arrangement similar to the arrangements shown in FIGS. 11A and 11B. In FIG. 11C, probe card 1101 is shown with top plate 1151 attached to a stiffener 1107 which is affixed to probe card PCB 1111. A probe insert is shown in cross section attached to the top plate 1151. In this example, the probe insert is attached to the top plate by thumb screws 1156. The probe insert includes a block 1165 attached to the probe insert PCB 1163 by screws 1170 from the device side surface of probe insert 1163. Other attachment types can be used to attach block 1165 to the probe insert PCB 1163, unlike the attachment of the top plate to the metal spacer block with thumb screws 1156, it is not necessary that the metal spacer block 1165 be removably attached to the probe insert PCB 1163, so rivets, clamps, bolts and nuts, pins and other permanent and removable types of attachments can be used for screws 1170. Interposer connectors 1155 are shown placed between the probe insert PCB 1163 and the probe card PCB 1111. As the top plate 1151 is assembled to the metal spacer block 1165 using the thumb screws 1156, the interposers 1155 are mechanically compressed between the probe card PCB 1111 and the probe insert PCB 1155 and the contacts on the interposers 1155 complete the electrical connections between pads on the probe insert PCB 1163 and the probe card PCB 1111; coupling the probe card 1101 to the probes 1164. Probes 1164 with probe tips 1159 are, in this example, cantilever probes that are supported by epoxy ring 1162 and connected at one end to electrical contacts on probe insert PCB 1163. The epoxy ring 1162 can be adhered to the block 1165, alternatively the epoxy ring is affixed to the probe insert PCB 1163. (Note that in the example of FIG. 11C, the alignment plate and alignment pins described hereinabove for use in placing the interposers 1155 in correct position are not shown, for clarity of the illustrations. See FIGS. 7A and 7B above where in an example the alignment plate is shown and the alignment pins are shown extending from the device side of the probe card.) In alternative arrangements the probes may be supported with other materials and other shapes, the epoxy ring is one useful example.

FIG. 11D illustrates the probe card 1101 in cross section and also shows a wafer transport stage 1127 and wafer chuck 1118, with a wafer 1114 mounted on it to show the use of the probe card 1101. In FIG. 11D the wafer transport stage 1127 is used to align contacts 1115 on a device under test on the wafer 1114 (a semiconductor device in this example) to the tips 1159 of probes 1164. The wafer is secured by wafer chuck 1118 using vacuum. (A backside tape and heating or cooling stage can be used but are omitted from FIG. 11D for simplicity of illustration.)

As shown in FIG. 11D, the wafer transport stage 1127 can bring the contacts 1115 to the probe tips 1159 and thus make electrical contact between the contacts 1115 and the probes 1164. Power, ground, and input signals can then be applied to the device under test using the probe card 1101 and probe insert, and probes 1159 will carry these signals to the device under test. Output signals that are output by the device under test can be captured using probes 1164 to receive the signals and probe card 1111 to transfer the signals to a tester (not shown) that is electrically coupled to the probe card 1101.

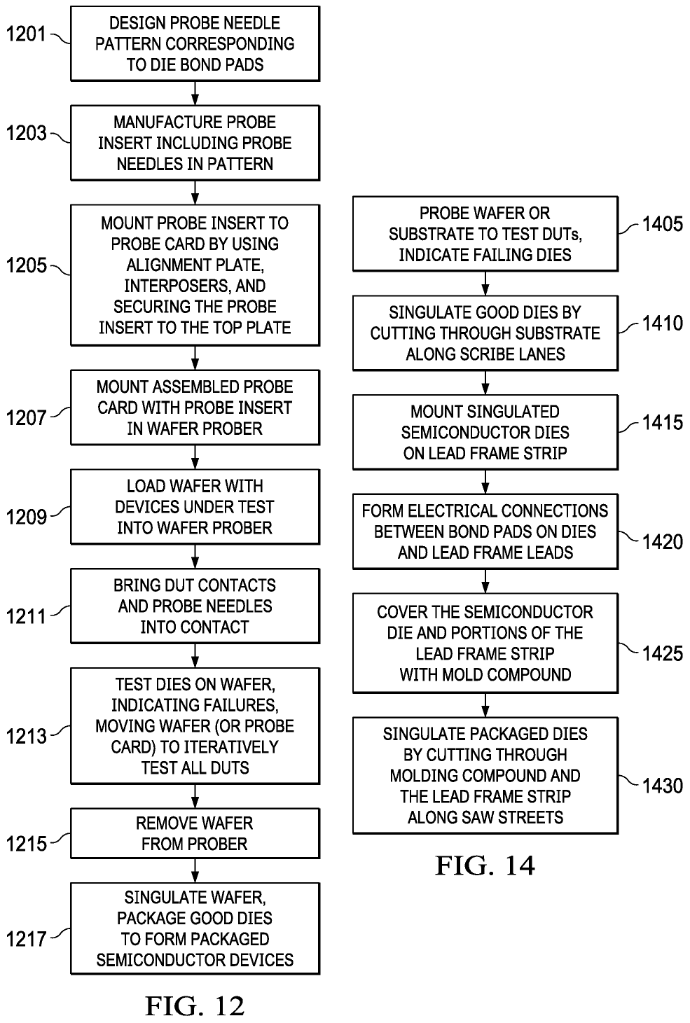

FIG. 12 illustrates a method in a flow diagram. In FIG. 12, the method begins at block 1201 by designing a probe needle pattern corresponding to the device under test. In an example, when testing semiconductor die, the probe pattern needs to correspond to the spacing and arrangement of bond pads on the semiconductor die. At step 1203 the probe insert is manufactured using the probe pattern. As shown above in FIG. 10A, the probe insert includes a printed circuit board and and a block as well as an epoxy ring or block that carries and supports the probe needles. The probe insert PCB can be about 4 inches on a side, in an example, and the alignment block can be about 3 inches on a side. Other sizes can be used to form additional arrangements, also the probe insert can take a variety of shapes, such as round, oval, rectangular, octagonal as needed or useful in a particular application.

As the method continues, at step 1205, the probe insert is removably mounted to the probe card. An alignment plate such as shown in FIG. 7A-7B can be used. The alignment plate can be installed on the tester side of the probe card and can carry alignment pins that extend through corresponding holes in the probe card. The top plate can then be secured to the tester side of the probe card, for example by using screws that attach the top plate to a stiffener of the probe card as described above.

The alignment plate can carry alignment pins that extend through the probe card and extend away from the wafer side of the probe card. The probe card, alignment plate and top plate can be permanently coupled together and form a reusable probe card assembly that can be used with a variety of removable probe inserts to test different DUTs. To attach the probe insert to the probe card, the interconnect interposers can first be placed on the device side of the probe card using the alignment plate pins and extending the alignment pins into the corresponding holes in the interposers. The probe insert can then be attached to the probe card. The alignment block of the probe insert extends into the central aperture of the probe card, and the top plate is attached to the metal block using aligned holes in the top plate, removable connectors such as thumb screws that extend through the holes in the top plate and which thread into threaded holes in the alignment block of the probe insert. The interconnect interposers are mechanically compressed as the thumb screws are tightened to bring the probe insert into position. Note that the aperture in the probe card PCB is large enough so that the alignment block on the probe insert can mate to the top plate by extending through the aperture without contacting the aperture on the probe card PCB. The probe insert and the probe card PCB mechanically compress the interposer spring contacts and thus the electrical contacts are made between the probe insert and the probe card PCB.

The top plate is attached to the probe card stiffener and is aligned to the probe card. In this example, the thumb screws and holes in the top plate are aligned with the probe insert metal block and the threaded holes in the metal block of the probe insert insure that the probe insert, and the probes themselves, are properly aligned to the probe card. The interposers are aligned to the probe card using the holes in the interposers and the alignment pins of the alignment plate. In the arrangements, the probe insert provides a removable set of probes arranged to test a selected device, and the probe insert can be replaced with another probe insert carrying a different set of probes for a different device under test in a few minutes by using the thumbscrews to detach the attached probe insert and to then attach a different probe insert. The probe card of the arrangements is reusable. The removable probe insert is smaller, simpler and faster to design and manufacture than a probe card. The probe insert circuit board can be free of passive devices and includes traces to couple the contact pads for the interposer to the probes, without complex routing patterns or additional devices. However, in an alternative arrangement, the probe insert may include passive components or other devices as needed in a particular application, and these variations form additional arrangements.

The method of FIG. 12 continues at block 1207, where the probe card and removable probe insert (now mounted to the probe card) are mounted into a wafer prober for use in testing devices.

At step 1209, the method continues by loading a wafer carrying DUTs into the wafer prober (in this example). As described hereinabove, the wafer can be secured using a vacuum chuck. The wafer is placed on a wafer transport stage within the wafer prober which can precisely move the wafer to align a DUT on the wafer with the probe needles that are carried by the removable probe insert, mounted to the probe card.

At step 1211, the wafer is moved so that a DUT is placed in contact with the probe needles. To ensure good electrical contact is made by all of the needles in the probe insert, an “overdrive” distance is used where the probe needles travel a slight distance past the specified contact point. Further, in some wafer probe operations, a “scratch” motion is made to cause the probe needles to penetrate any native oxide that has formed on the contacts of the DUT. In this way, the probe needles are more likely to make a low resistance electrical contact to the bond pads of the DUT.

At step 1213, the test is conducted. After the first DUT is tested, the method remains in step 1213, testing other DUTs on the wafer in an iterative fashion. This can continue until the wafer is completely tested. For example, the wafer transport stage may contact the probe needles to DUTs by traversing rows of devices, and then columns, or in a raster scan pattern, or in an up and down, or side to side, pattern to cover the wafer. If a large number of devices on a given wafer are failing, the test need not continue until all devices on the wafer are tested, instead the wafer can be replaced by another in identifying good devices for completion.

During testing, the tester can keep a “map” of the DUTs on the wafer and record failing devices, and can keep track of “fast” or high performing devices and “slow” but functional devices for use in sorting the devices. Failing devices can be marked with a visual indicator, such as a dot, or alternatively, good devices can be marked. The wafer map or markings can be used in subsequent steps to make sure that the packaging steps are performed only on “known good” die (KGD), saving time, material and costs associated with packaging bad devices.

At step 1215, the wafer is removed from the wafer prober.

At step 1217, the DUTs, in this example semiconductor devices, can be singulated from the wafer and then packaged. The test results, in the form of marked devices of using a wafer map, can be used to aid in the step to singulate and package only good devices.

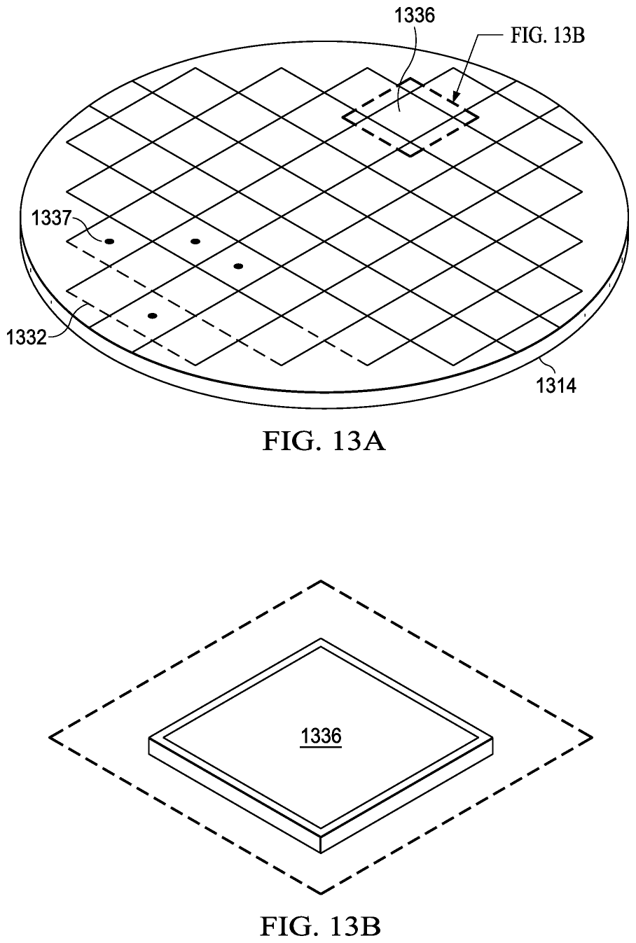

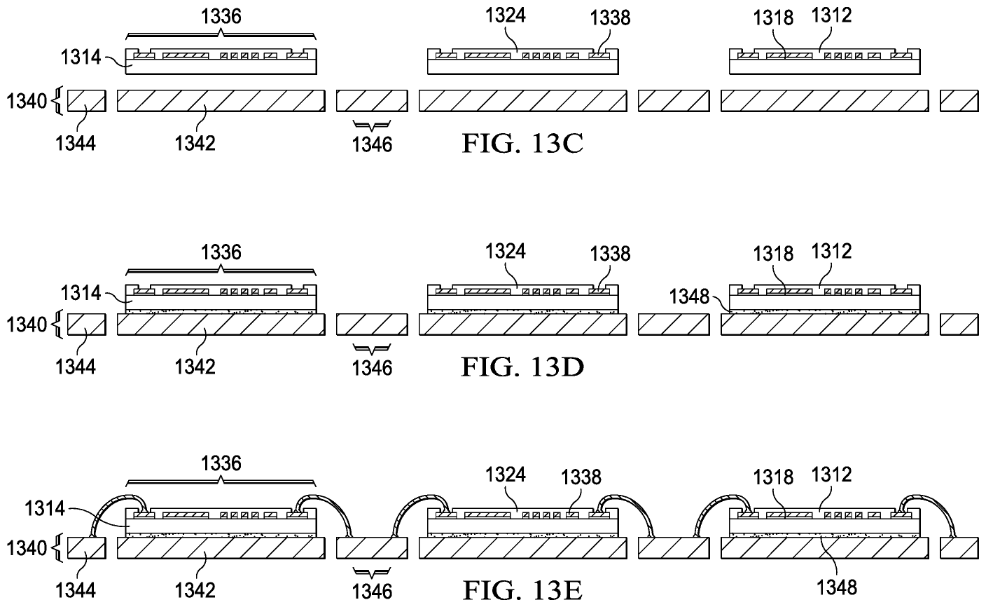

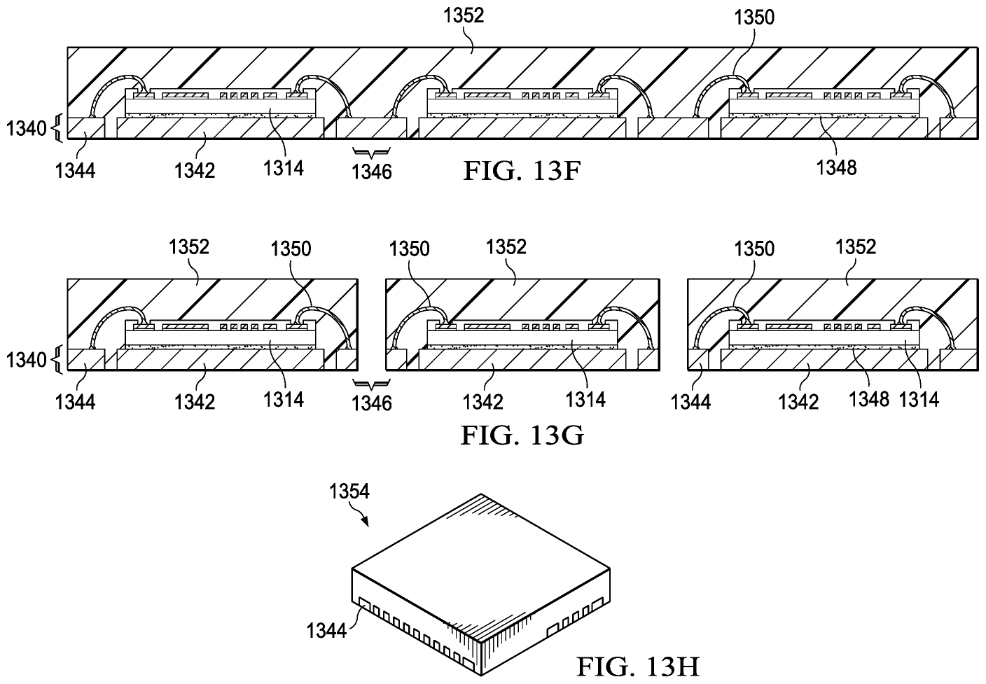

FIGS. 13A-13G illustrate major steps in the manufacture of a packaged electronic device after using the probe insert of the arrangements for testing. The steps of FIG. 13A-13G are shown in a flow diagram in FIG. 14. In FIGS. 13A-13G similar reference labels are used for similar elements shown in FIG. 11D, for clarity. For example, wafer 1314 in FIGS. 13A-13G corresponds to wafer 1114 in FIG. 11D. FIG. 13A is a wafer 1314 showing a semiconductor device 1336 prior to a singulation operation. Scribe lanes 1335 (horizontal as shown in FIG. 13A) and 1332 (vertical as oriented in FIG. 13A) separate the semiconductor die from one another on the wafer. In this example die shown marked with a black “dot” 1337 are die that failed the tests at wafer probe as described hereinabove (step 1405 in FIG. 14).

FIG. 13B (step 710) is an expanded view of one of the singulated die 1336, obtained by cutting through a semiconductor wafer along the scribe lanes 1332, 1334 to separate the die from one another, and then removing one “known good” device 1336 from the remaining die on wafer 1314 (step 1410 in FIG. 14). Pick and place tools can select a singulated device from the wafer after sawing or dicing operations.

In FIG. 13C, singulated die 1336 are aligned to a die mount pad 1342 on a package substrate. In this example the package substrate is a lead frame strip 1340, but the package substrate can also be tape-based and film-based package substrates carrying conductors; premolded lead frame (PMLF) strips that combine conductors and mold compound in a structure, ceramic substrates, laminate substrates with multiple layers of conductors and insulator layers; molded interconnect substrates (MIS) that include leads in a mold compound, and printed circuit board substrates of ceramic, fiberglass or resin, or glass fiber reinforced epoxy substrates such as FR4. In a device stacking example, the package substrate can also be another semiconductor device or wafer. In this particular example using a lead frame strip, the lead frame strip is comprised of several individual lead frames (die mount pad 1342 plus leads 1344) joined together by saw streets 1346 and made of lead frame material such as copper or a copper alloy.

In FIG. 13D, singulated die 1336 (step 1415) are shown mounted on the die mount pad 1342 using a bonding agent 1348 such as solder or an adhesive, in one example a die attach compound is used.

In FIG. 13E, bondpads 1338 on the die 1336 are electrically connected to leads 1344 on the package substrate (lead frame strip 1340) with a conductor 1350 (step 1420). In FIG. 13E the conductor 1350 is a wirebond. In an alternative, a “flip chip” approach has the die positioned with the bond pads facing the package substrate and bond pads aligned to corresponding lands on the package substrate, and solder connections are made using solder bumps or balls, or copper columns with solder bumps can be used.

In FIG. 13F, the die 1336, the conductors 1350, and portions of the leads 1344 are covered with a mold compound 1352 such as a filled epoxy (see step 1425 in FIG. 14).

In FIG. 13G, individual packaged die 1354 are singulated (see step 1430 in FIG. 14) by cutting through the saw streets 1346 on the package substrate 1340 (here a lead frame strip.)

FIG. 13H is a projection view of a commercially manufactured quad flat no-lead (QFN) packaged semiconductor device 1354 including a single semiconductor die that was tested using the arrangements. The leads 1344 are exposed from the package body for use in making connections to the packaged semiconductor device.

In the arrangements, a probe insert is removably affixed to a probe card. While the example arrangements used for the description herein show a probe insert with a top block to affix the probe insert to the probe card, in alternative arrangements, the probe insert can be affixed to the probe card in another fashion. In the examples shown and described herein, the top block is affixed to a top plate that is attached to the probe card. In additional alternative arrangements, a probe insert can be removably affixed to a probe card using other means. The arrangements provide a probe insert that carries probes for a particular device under test, with a reusable probe card, and the probe insert is removably attached to the probe card while electrical connections are made from the probe insert to the probe card.

Modifications are possible in the described arrangements, and other alternative arrangements are possible within the scope of the claims.

What is claimed is:

1. A device, comprising:
a probe card with a tester side surface and a device side surface opposite the tester side surface;
a probe insert having a first surface that is removably affixed to the device side surface of the probe card, and at least one or more probes extending from a second surface of the probe insert that is opposite the first surface of the probe insert.

2. The device of claim 1, wherein the probes comprise cantilever probe needles.

3. The device of claim 1, wherein the probes are blade probes.

4. The device of claim 1, wherein the probes are vertical probes.

5. The device of claim 1, and further comprising at least one interposer having electrical terminals extending through a dielectric material so the electrical terminals have ends on two opposite sides of the at least one interposer, the at least one interposer placed between the second surface of the probe card and the first surface of the probe insert.

6. The device of claim 5 wherein the at least one interposer is mechanically compressed between the probe card and the probe insert and the electrical terminals of the at least one interposer make electrical contact between first pads on the probe card and corresponding second pads on the probe insert.

7. The device of claim 6 wherein the probe insert is a printed circuit board.

8. The device of claim 7, and further comprising an alignment plate on the first surface of the probe card and having pins extending through the probe card and which extend away from the second surface of the probe card in a direction perpendicular to the second surface.

9. The device of claim 8, wherein the pins of the alignment plate extend through corresponding openings in the at least one interposer.

10. The device of claim 1, wherein the probe card further comprises a top plate that has a portion that overlies a central aperture of the probe card, the top plate configured for attaching to a block mounted on the first surface of the probe insert.

11. The device of claim 10, wherein the block has a thickness above the first surface of the probe insert and the block has a surface area smaller than the opening for the central aperture, so that when the probe insert is removably affixed to the probe card, the block of the probe insert extends through the probe card in the central aperture.

12. The device of claim 11, wherein the top plate portion has a plurality of through holes and the block of the probe insert has threaded openings in positions that correspond to the plurality of through holes of the top plate.

13. The device of claim 12 and further comprising fasteners configured for removably attaching the probe insert to the probe card, the fasteners extending through the through holes in the top plate portion and threaded into the threaded openings in the block of the probe insert.

14. The device of claim 1, wherein the probe card is a printed circuit board with conductive traces coupling one end of the probes and to electrical contacts on the first surface of the probe insert.

15. A method for making a packaged semiconductor device, comprising:
removably affixing a probe insert to a probe card having a tester side and a device side, the probe insert affixed to the device side of the probe card and including probes extending from the probe insert with probe tips arranged to correspond to a pattern of bond pads on a semiconductor device to be tested;
mounting the probe card in a wafer prober with the probe side of the probe card facing towards a device under test area;
placing a semiconductor substrate in device under test area of the wafer prober, the semiconductor substrate including a plurality of semiconductor devices with bond pads arranged in the patter, the semiconductor substrate placed with the bond pads facing the probe side of the probe card, the probe tips extending from the probe card towards the semiconductor substrate;
moving the semiconductor substrate relative to the probe card to place probe tips into physical contact with the bond pads of at least one semiconductor device on the semiconductor substrate;
using the probes on the probe insert, performing a test of the semiconductor device in contact with the probe tips by transmitting signals to the semiconductor device and receiving signals from the semiconductor device;
determining whether the semiconductor device passed the test; and
if the semiconductor device passed the test, removing the semiconductor device from the semiconductor substrate and packaging the semiconductor device to form a packaged semiconductor device.

16. The method of claim 15, and further comprising:
iteratively performing a test of the semiconductor devices on the semiconductor substrate by:
selecting another semiconductor device for test;
moving the probe card and the semiconductor substrate relative to one another to position the another semiconductor device for test in alignment with the probe tips;
contacting the bond pads of the another semiconductor device under test with the probe tips;
performing the test on the another semiconductor device;
determining whether the another semiconductor device passed the test; and
continuing the selecting, moving, contacting, performing; and determining on the remaining semiconductor devices on the semiconductor substrate.

17. The method of claim 15, wherein packaging the semiconductor devices further comprises:
separating a semiconductor device from the semiconductor substrate;
mounting the semiconductor device on a packaging substrate;
electrically connecting the semiconductor to terminals on the packaging substrate;
at least partially covering the semiconductor device and the packaging substrate with dielectric material; and
separating the semiconductor device to form an individual packaged semiconductor device.

18. A method for manufacturing devices, comprising:
removably affixing a probe insert carrying probes with probe tips extending from the probe insert to a device side surface of a probe card;
mounting the probe card in a wafer prober, the probes extending from the probe insert towards a device area in the wafer prober;
placing a device under test in the device area;
moving the probe card and the device under test relative to one another to cause the probe tips of the probe insert to physically contact terminals on the device under test;
performing tests on the device under test; and′ determining whether the device passes the test.

19. The method of claim 18, wherein the probe tips extend from the probe insert to form a pattern that corresponds to a pattern of the terminals on the device under test.

20. The method of claim 18, wherein the probes are cantilever probe needles.

21. The method of claim 18, wherein the probes are blade probes.

22. The method of claim 18 wherein the probe insert is a printed circuit board.

23. The method of claim 18, wherein the probe insert includes an alignment block affixed to a prober side surface opposite a device under test side surface of the probe insert, the alignment block being arranged to be removably attached to a top plate of the probe card, the probe card having a central aperture with an opening larger than the alignment block, the top plate being arranged to mate with the alignment block which extends into the central aperture when the probe insert is removably affixed to the top plate of the probe card.

24. The method of claim 23, wherein affixing the probe insert to the probe card further comprises placing interposers between the prober side of the probe insert and the device side surface of the probe card, the interposer making electrical connection between the probe card and the probe insert.

25. The method of claim 24, wherein the interposers include spring terminals that make electrical connections when mechanically compressed.

26. The method of claim 18, wherein the probe card is a printed circuit board with connection terminals for coupling to a tester.

27. The method of claim 18, wherein the probe card and the probe insert are printed circuit boards having conductive traces coupled to pads formed in correspondence for making electrical connections between the probe card and the probe insert.

28. The method of claim 18, and further comprising:
the probe insert is a first probe insert, and removing the first probe insert from the probe card; and
removably affixing a second probe insert having probe tips arranged for a different device under test than the first probe insert to the probe card.

29. The method of claim 28, and further comprising using the probe card and the second probe insert, performing tests on the different device under test.

30. The method of claim 18, wherein the device under test is a semiconductor device on a semiconductor substrate.

31. The method of claim 18, wherein the device under test is a packaged semiconductor device.
